(19) United States
(12) Patent Application Publication
(10) Pub. No.: US 2024/0304739 A1
(43) Pub. Date: Sep. 12, 2024

(54) SEMICONDUCTOR LIGHT-RECEIVING DEVICE

(71) Applicant: SUMITOMO ELECTRIC INDUSTRIES, LTD., Osaka (JP)

(72) Inventors: Takashi KATO, Osaka-shi (JP); Yasuhiro IGUCHI, Osaka-shi (JP)

(73) Assignee: SUMITOMO ELECTRIC INDUSTRIES, LTD., Osaka (JP)

(21) Appl. No.: 18/595,878

(22) Filed: Mar. 5, 2024

(30) Foreign Application Priority Data
Mar. 7, 2023 (JP) 2023-034592

(51) Int. Cl. H01L 31/0304; H01L 31/0216; H01L 31/0352

(52) U.S. Cl. CPC H01L 31/03046; H01L 31/02164; H01L 31/035236

(57) ABSTRACT

A semiconductor light-receiving device includes an indium phosphide substrate, a first III-V compound semiconductor layer of n-type, a second III-V compound semiconductor layer of p-type, an optical absorption layer disposed between the first III-V compound semiconductor layer and the second III-V compound semiconductor layer, a hole barrier layer disposed between the first III-V compound semiconductor layer and the optical absorption layer, and an electron barrier layer disposed between the second III-V compound semiconductor layer and the optical absorption layer. The first III-V compound semiconductor layer is disposed between the indium phosphide substrate and the optical absorption layer.

### CROSS REFERENCE TO RELATED APPLICATIONS

This application claims priority based on Japanese Patent Application No. 2023-034592 filed on Mar. 7, 2023, and the entire contents of the Japanese patent application are incorporated herein by reference.

### TECHNICAL FIELD

The present disclosure relates to a semiconductor light-receiving device.

### BACKGROUND

PTL 1 discloses a semiconductor optical device including an n-type gallium antimonide (GaSb) substrate. An n-type bulk semiconductor layer, an n-type superlattice layer, a hole barrier layer, a separator layer, an optical absorption layer, an electron barrier layer, a p-type superlattice layer, and a p-type bulk semiconductor layer are disposed in this order on the GaSb substrate.

Non-PTL 1 discloses a photodiode including a GaSb substrate doped with tellurium (Te). A GaSb layer, an n-type contact layer, a hole barrier layer, an optical absorption layer, an electron barrier layer, and a p-type contact layer are disposed in this order on the GaSb substrate.

Non-PTL 2 discloses a photodetector including an indium phosphide (InP) substrate. An n-type indium gallium arsenide (InGaAs) layer, a superlattice layer, an optical absorption layer, a p-type indium aluminum arsenide (InAIAs) layer, a p-type aluminum arsenic antimonide (AIAsSb) layer, and a p-type InGaAs layer are disposed in this order on the InP substrate. The superlattice layer includes an InGaAs layer and a gallium arsenide antimonide (GaAsSb) layer. The optical absorption layer is a non-doped InGaAs layer. The AIAsSb layer functions as an electron barrier layer.
PTL 1: Japanese Unexamined Patent Application Publication No. 2020-126894
Non-PTL 1: Zhaobing Tian, et al, “Low Dark Current Structures for Long-wavelength Type-II Strained Layer Superlattice Photodiodes” Proc. of SPIE, Vol. 8704, 2013, 870415
Non-PTL 2: Jingyi Wang, et al, “InP-Based Broadband Photodetectors With InGaAs/GaAsSb Type-II Superlattice” IEEE Electron Device Letters, Vol. 43, No. 5, 2022, p. 757-760

### SUMMARY

A semiconductor light-receiving device according to an aspect of the present disclosure includes an indium phosphide substrate, a first III-V compound semiconductor layer of n-type, a second III-V compound semiconductor layer of p-type, an optical absorption layer disposed between the first III-V compound semiconductor layer and the second III-V compound semiconductor layer, a hole barrier layer disposed between the first III-V compound semiconductor layer and the optical absorption layer, and an electron barrier layer disposed between the second III-V compound semiconductor layer and the optical absorption layer. The first III-V compound semiconductor layer is disposed between the indium phosphide substrate and the optical absorption layer.

### BRIEF DESCRIPTION OF THE DRAWINGS

FIG. 1 is a cross-sectional view schematically showing a semiconductor light-receiving device according to an embodiment.

FIG. 2 is a cross-sectional view schematically showing an optical absorption layer included in the semiconductor light-receiving device of FIG. 1.

FIG. 3 is a graph showing an example of the relationship between a quantum efficiency and a wavelength of a semiconductor light-receiving device.

FIG. 4 is a graph showing an example of an energy band diagram of a semiconductor light-receiving device of a first experiment.

FIG. 5 is a graph showing an example of an energy band diagram of a semiconductor light-receiving device of a second experiment.

FIG. 6 is a graph showing examples of the relationship between dark current and bias voltage of semiconductor light-receiving devices of a first experiment and a second experiment.

### DETAILED DESCRIPTION

In the semiconductor light-receiving device including the InP substrate, the hole barrier layer is not disposed between the optical absorption layer and the n-type InGaAs layer.

The present disclosure provides a semiconductor light-receiving device capable of reducing dark current.

### Description of Embodiments of Present Disclosure

First, embodiments of the present disclosure will be listed and described.
(1) A semiconductor light-receiving device includes an indium phosphide substrate, a first III-V compound semiconductor layer of n-type, a second III-V compound semiconductor layer of p-type, an optical absorption layer disposed between the first III-V compound semiconductor layer and the second III-V compound semiconductor layer, a hole barrier layer disposed between the first III-V compound semiconductor layer and the optical absorption layer, and an electron barrier layer disposed between the second III-V compound semiconductor layer and the optical absorption layer. The first III-V compound semiconductor layer is disposed between the indium phosphide substrate and the optical absorption layer.

In the semiconductor light-receiving device, the hole barrier layer suppresses a flow of holes (minority carriers) in the first III-V compound semiconductor layer of n-type into the optical absorption layer. The electron barrier layer suppresses the flow of electrons (minority carriers) in the second III-V compound semiconductor layer of p-type into the optical absorption layer. Therefore, the dark current due to the minority carriers flowing into the optical absorption layer can be reduced.
(2) In the above (1), the optical absorption layer may have a type-II superlattice structure.
(3) In the above (2), the superlattice structure may include a gallium indium arsenide layer and a gallium arsenide antimonide layer.
(4) In any one of the above (1) to (3), the hole barrier layer may be an n-type aluminum gallium indium arsenide layer.
(5) In any one of the above (1) to (4), the hole barrier layer may be a bulk layer. In this case, the hole barrier layer does not have a superlattice structure.
(6) In any one of the above (1) to (5), the electron barrier layer may be a p-type aluminum gallium arsenide antimonide layer. In this case, the composition ratio of aluminum can be made smaller than that of AIAsSb. Therefore, oxidation of the electron barrier layer due to oxidation of aluminum can be suppressed.
(7) In any one of the above (1) to (6), the electron barrier layer may be a bulk layer. In this case, the electron barrier layer does not have a superlattice structure.
(8) In any one of the above (1) to (7), the semiconductor light-receiving device may further include a non-doped third III-V compound semiconductor layer disposed between the electron barrier layer and the optical absorption layer. In this case, a p-type dopant can be prevented from diffusing from the electron barrier layer into the optical absorption layer.
(9) In the above (8), the third III-V compound semiconductor layer may contain gallium indium arsenide antimonide. In this case, a notch formed at the upper end of the valence band can be made smaller than that of GaInAs. As a result, holes generated by light absorption in the optical absorption layer easily flow into the second III-V compound semiconductor layer.
(10) In any one of the above (1) to (9), the semiconductor light-receiving device may further include a non-doped fourth III-V compound semiconductor layer disposed between the hole barrier layer and the optical absorption layer. In this case, an n-type dopant can be prevented from diffusing from the hole barrier layer into the optical absorption layer.
(11) In the above (10), the fourth III-V compound semiconductor layer may contain gallium indium arsenide.

### Details of Embodiments of Present Disclosure

Hereinafter, embodiments of the present disclosure will be described in detail with reference to the accompanying drawings. In the description of the drawings, the same or equivalent elements are denoted by the same reference numerals, and redundant description thereof will be omitted.

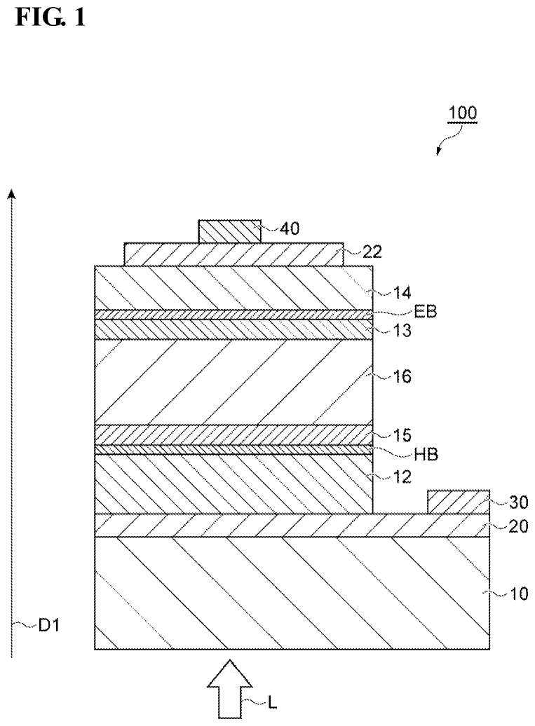

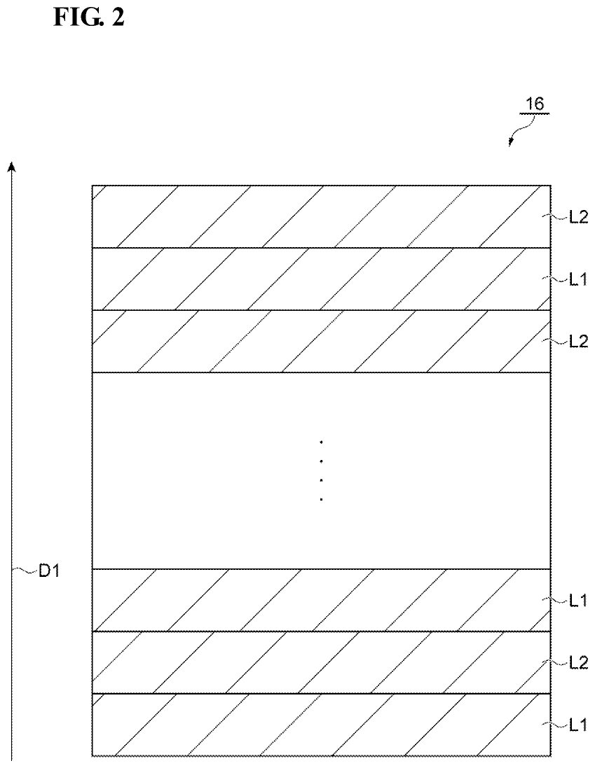

FIG. 1 is a cross-sectional view schematically showing a semiconductor light-receiving device according to an embodiment. FIG. 2 is a cross-sectional view schematically showing an optical absorption layer included in the semiconductor light-receiving device of FIG. 1. A semiconductor light-receiving device 100 shown in FIG. 1 is, for example, a photodiode. Semiconductor light-receiving device 100 includes an indium phosphide (InP) substrate 10, a first III-V compound semiconductor layer 12 of n-type, a second III-V compound semiconductor layer 14 of p-type, and an optical absorption layer 16. Optical absorption layer 16 is disposed between first III-V compound semiconductor layer 12 and second III-V compound semiconductor layer 14.

Semiconductor light-receiving device 100 includes a hole barrier layer HB and an electron barrier layer EB. Hole barrier layer HB is disposed between first III-V compound semiconductor layer 12 and optical absorption layer 16. The energy at the upper end of a valence band of hole barrier layer HB is smaller than the energy at the upper end of a valence band of first III-V compound semiconductor layer 12. Hole barrier layer HB prevents holes from moving from optical absorption layer 16 to first III-V compound semiconductor layer 12. Electron barrier layer EB is disposed between second III-V compound semiconductor layer 14 and optical absorption layer 16. The energy at the lower end of the conduction band of electron barrier layer EB is larger than the energy at the lower end of the conduction band of second III-V compound semiconductor layer 14. Electron barrier layer EB prevents electrons from moving from optical absorption layer 16 to second III-V compound semiconductor layer 14.

InP substrate 10 may be a semi-insulating substrate. First III-V compound semiconductor layer 12 may be disposed between main surface of InP substrate 10 and optical absorption layer 16. The main surface of InP substrate 10 may be a (100) plane.

First III-V compound semiconductor layer 12 may be an n-type gallium indium arsenide (GaₓIn₁₋ₓAs or GaInAs) layer. The x is a gallium (Ga) composition. The x is greater than 0 and less than 1. The x may be from 0.46 to 0.48. The concentration of an n-type dopant in first III-V compound semiconductor layer 12 may be from 5×10¹⁷ cm⁻³ to 3×10¹⁹ cm⁻³. The thickness of first III-V compound semiconductor layer 12 may be from 0.2 μm to 3 μm.

Second III-V compound semiconductor layer 14 may be a p-type gallium indium arsenide (GaₓIn₁₋ₓAs or GaInAs) layer. The x is a gallium (Ga) composition. The x is greater than 0 and less than 1. The x may be from 0.46 to 0.48. The concentration of a p-type dopant in second III-V compound semiconductor layer 14 may be from 5×10¹⁷ cm⁻³ to 3×10¹⁹ cm⁻³. The thickness of second III-V compound semiconductor layer 14 may be from 0.2 μm to 3 μm.

Optical absorption layer 16 may be a non-doped III-V compound semiconductor layer. In the present specification, “non-doped” means that a dopant is not intentionally doped. Therefore, the “non-doped” may have the concentration of a p-type dopant of less than 1×10¹⁵ cm⁻³ or may have the concentration of an n-type dopant of less than 1×10¹⁵ cm⁻³. Optical absorption layer 16 may have a type-II superlattice structure. As shown in FIG. 2, the superlattice structure of optical absorption layer 16 may include a non-doped GaₓIn₁₋ₓAs (or GaInAs) layer L1 and a non-doped GaAs_{y}Sb_{1-y} (or GaAsSb) layer L2. The x is a gallium (Ga) composition. The x is greater than 0 and less than 1. The x may be from 0.4 to 0.7. The y is the arsenic (As) composition. The y may be from 0.2 to 0.6. GaₓIn₁₋ₓAs layer L1 and GaAs_{y}Sb_{1-y} layer L2 may be alternately arranged along a first direction D1. GaₓIn₁₋ₓAs layer L1 may be positioned to form a lower surface of optical absorption layer 16 closest to first III-V compound semiconductor layer 12. Thus, GaₓIn₁₋ₓAs layer L1 can be formed with good crystallinity on a semiconductor layer. GaAs_{y}Sb_{1-y} layer L2 may be positioned to form an upper surface of optical absorption layer 16 closest to second III-V compound semiconductor layer 14. This allows the semiconductor layer to be formed on GaAs_{y}Sb_{1-y} layer L2 with good crystallinity. The number of pairs (periods) of GaₓIn₁₋ₓAs layer L1 and GaAs_{y}Sb_{1-y} layer L2 may be from 200 to 400. The thickness of GaₓIn₁₋ₓAs layer L1 may be from 3 nm to 6 nm. The thickness of GaAs_{y}Sb_{1-y} layer L2 may be from 3 nm to 6 nm. The thicknesses of GaAs_{y}Sb_{1-y} layer L2 may be the same as or different from the thicknesses of GaₓIn₁₋ₓAs layer L1.

Electron barrier layer EB may be a p-type III-V compound semiconductor layer. Electron barrier layer EB may be a p-type aluminum gallium arsenide antimonide (AlₓGa₁₋ₓAs_{y}Sb_{1-y} or AlGaAsSb) layer. The x is an aluminum (Al) composition. The y is the arsenic (As) composition. The x is greater than 0 and less than 1. The x may be from 0.6 to 0.85. The y is greater than 0 and less than 1. The y may be from 0.5 to 0.6. Electron barrier layer EB may have the concentration of a p-type dopant lower than the concentration of a p-type dopant of second III-V compound semiconductor layer 14. The concentration of a p-type dopant in electron barrier layer EB may be from 5×10¹⁷ cm-3 to 2×10¹⁹ cm⁻³. Electron barrier layer EB may have a thickness smaller than that of second III-V compound semiconductor layer 14. The thickness of Electron barrier layer EB may be from 5 nm to 50 nm. Electron barrier layer EB may be a bulk layer. Electron barrier layer EB may be a single layer without having a superlattice structure.

Hole barrier layer HB may be an n-type III-V compound semiconductor layer. Hole barrier layer HB may be an n-type aluminum gallium indium arsenide AlₓGa_{y}In_{1-x-y}As or AlGaInAs) layer. The x is an aluminum (Al) composition. The y is the gallium (Ga) composition. The x is greater than 0 and less than 1. The x may be from 0.2 to 0.45. The y is greater than 0 and less than 1. The y may be from 0.025 to 0.28. Hole barrier layer HB may have the concentration of an n-type dopant lower than the concentration of an n-type dopant of first III-V compound semiconductor layer 12. The concentration of an n-type dopant in hole barrier layer HB may be from 5×10¹⁷ cm⁻³ to 2×10¹⁹ cm⁻³. Hole barrier layer HB may have a thickness smaller than that of first III-V compound semiconductor layer 12. The thickness of Hole barrier layer HB may be from 5 nm to 50 nm. Hole barrier layer HB may be a bulk layer. Hole barrier layer HB may be a single layer without having a superlattice structure.

Semiconductor light-receiving device 100 may further include a non-doped third III-V compound semiconductor layer 13 disposed between electron barrier layer EB and optical absorption layer 16. Third III-V compound semiconductor layer 13 can suppress the diffusion of the p-type dopant from electron barrier layer EB to optical absorption layer 16. Third III-V compound semiconductor layer 13 may include gallium indium arsenide antimonide (GaₓIn₁₋ₓAs_{y}Sb_{1-y} or GaInAsSb). The x is a gallium (Ga) composition. The y is the arsenic (As) composition. The x is greater than 0 and less than 1. The x may be from 0.8 to 0.95. The y is greater than 0 and less than 1. The y may be from 0.55 to 0.70. Third III-V compound semiconductor layer 13 may have a thickness smaller than that of second III-V compound semiconductor layer 14. Third III-V compound semiconductor layer 13 may have a thickness greater than that of electron barrier layer EB. The thickness of third III-V compound semiconductor layer 13 may be from 20 nm to 80 nm.

Semiconductor light-receiving device 100 may further include a non-doped fourth III-V compound semiconductor layer 15 disposed between hole barrier layer HB and optical absorption layer 16. Fourth III-V compound semiconductor layer 15 can suppress the diffusion of the n-type dopant from hole barrier layer HB to optical absorption layer 16. Fourth III-V compound semiconductor layer 15 may include gallium indium arsenide (GaₓIn₁₋ₓAs or GaInAs). The x is a gallium (Ga) composition. The x is greater than 0 and less than 1. The x may be from 0.4 to 0.5. Fourth III-V compound semiconductor layer 15 may have a thickness smaller than that of first III-V compound semiconductor layer 12. Fourth III-V compound semiconductor layer 15 may have a thickness greater than that of hole barrier layer HB. The thickness of fourth III-V compound semiconductor layer 15 may be from 20 nm to 80 nm.

Semiconductor light-receiving device 100 may further include a III-V compound semiconductor layer 20 of n-type. III-V compound semiconductor layer 20 is disposed between InP substrate 10 and first III-V compound semiconductor layer 12. III-V compound semiconductor layer 20 may be a contact layer. III-V compound semiconductor layer 20 has the concentration of an n-type dopant higher than the concentration of an n-type dopant of first III-V compound semiconductor layer 12. III-V compound semiconductor layer 20 may be a GaInAs layer. An electrode 30 may be connected to III-V compound semiconductor layer 20.

Semiconductor light-receiving device 100 may further include a III-V compound semiconductor layer 22 of p-type. Second III-V compound semiconductor layer 14 is disposed between III-V compound semiconductor layer 22 and electron barrier layer EB. III-V compound semiconductor layer 22 may be a contact layer. III-V compound semiconductor layer 22 has the concentration of a p-type dopant higher than the concentration of a p-type dopant of second III-V compound semiconductor layer 14. III-V compound semiconductor layer 22 may be a GaInAs layer. An electrode 40 may be connected to III-V compound semiconductor layer 22.

InP substrate 10, III-V compound semiconductor layer 20, first III-V compound semiconductor layer 12, hole barrier layer HB, fourth III-V compound semiconductor layer 15, optical absorption layer 16, third III-V compound semiconductor layer 13, electron barrier layer EB, second III-V compound semiconductor layer 14, and III-V compound semiconductor layer 22 can be arranged in this order along first direction D1. First direction D1 may be orthogonal to the main surface of InP substrate 10. First direction D1 may be a thickness direction of optical absorption layer 16. First direction D1 may be a direction from first III-V compound semiconductor layer 12 toward second III-V compound semiconductor layer 14. First direction D1 may be a crystal growth direction.

Semiconductor light-receiving device 100 may detect an incident light L. Incident light L may be visible light or infrared light having a wavelength of 0.4 μm to 4 μm. Incident light L may proceed in first direction D1. Incident light L may be incident on optical absorption layer 16 through InP substrate 10. Semiconductor light-receiving device 100 may have a cut-off wavelength (absorption edge wavelength) of 2 μm to 4 μm. Semiconductor light-receiving device 100 can be used in a spectroscopic system of a gas analyzer, an imaging system, or an optical communication system.

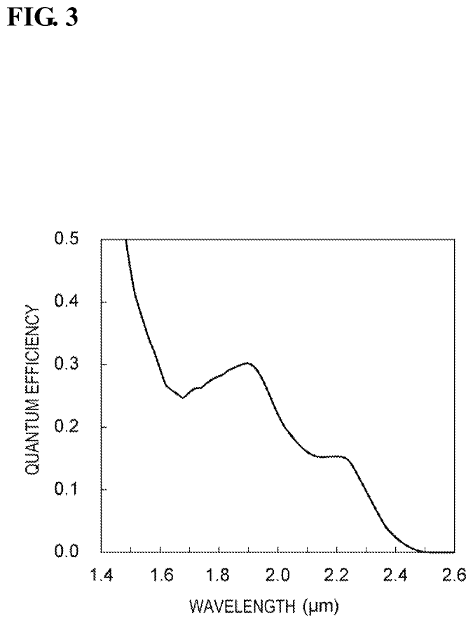

FIG. 3 is a graph showing an example of the relationship between a quantum efficiency and a wavelength of a semiconductor light-receiving device. In the graph of FIG. 3, the horizontal axis represents the wavelength (μm) of light absorbed by the optical absorption layer. The vertical axis represents the quantum efficiency of the semiconductor light-receiving device. In the example shown in FIG. 3, the optical absorption layer absorbs light having a wavelength of 2.5 μm or less. That is, the cutoff wavelength is about 2.5 μm.

According to semiconductor light-receiving device 100, hole barrier layer HB suppresses holes (minority carriers) in first III-V compound semiconductor layer 12 of n-type from flowing into optical absorption layer 16. Electron barrier layer EB suppresses the flow of electrons (minority carriers) in second III-V compound semiconductor layer 14 of p-type into optical absorption layer 16. Therefore, the dark current due to the minority carriers flowing into optical absorption layer 16 can be reduced.

When electron barrier layer EB is an AlGaAsSb layer, the composition ratio of aluminum can be made smaller than that of AIAsSb. Therefore, the oxidation of electron barrier layer EB due to the oxidation of aluminum can be suppressed.

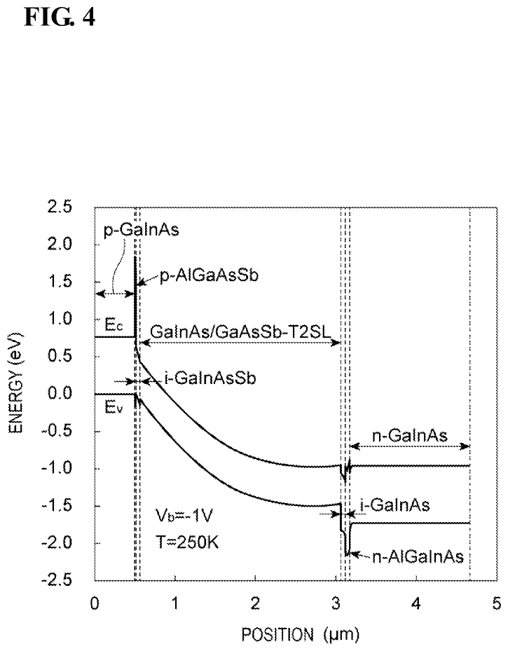

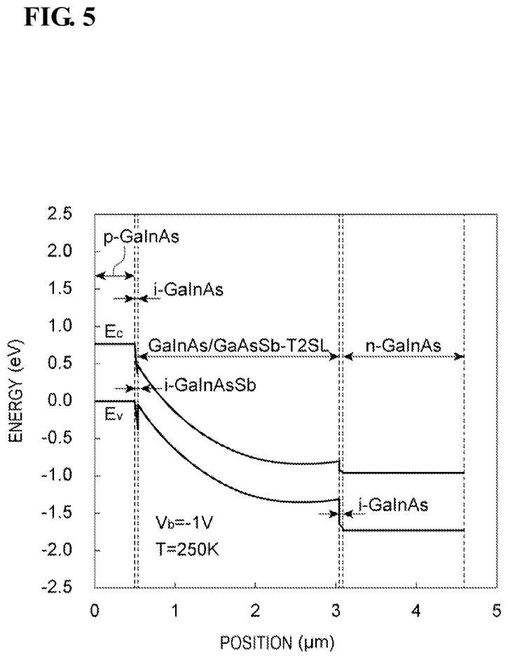

When third III-V compound semiconductor layer 13 includes gallium indium arsenide antimonide, the notch formed at the upper end of the valence band (see FIGS. 4 and 5) can be made smaller than that of GaInAs. As a result, holes generated by light absorption in optical absorption layer 16 easily flow into second III-V compound semiconductor layer 14.

Hereinafter, various experiments performed for evaluating semiconductor light-receiving device 100 will be described. The experiments described below are not intended to limit the invention.

### First Experiment

A semiconductor light-receiving device of a first experiment has the following structure similar to semiconductor light-receiving device 100.
InP substrate 10: InP substrate,
First III-V compound semiconductor layer 12: n-type GaₓIn₁₋ₓAs(x=0.47) layer, concentration of n-type dopant of 2×10¹⁸ cm⁻³, 1.5 μm thick,
Hole barrier layer HB: n-type AlₓGa_{y}In_{1-x-y}As (x=0.3, y=0.17) layer,
Fourth III-V compound semiconductor layer 15: i-type GaₓIn₁₋ₓAs (x=0.47) layer,
Optical absorption layer 16: type-II superlattice structure including GaₓIn₁₋ₓAs (x=0.47) layers and GaAs_{y}Sb_{1-y} (y=0.51) layers, 280 periods,
Third III-V compound semiconductor layer 13: i-type GaₓIn₁₋ₓAs_{y}Sb_{1-y} (x=0.9, y=0.6) layer, 50 nm thick,
Electron barrier layer EB: p-type AlₓGa₁₋ₓAs_{y}Sb_{1-y} (x=0.8, y=0.55) layer, concentration of p-type dopant of 1×10¹⁸ cm⁻³, 20 nm thick,
Second III-V compound semiconductor layer 14: p-type GaₓIn₁₋ₓAs (x=0.47) layer, concentration of p-type dopant of 1×10¹⁹ cm⁻³, 0.5 μm thick.

### Second Experiment

A semiconductor light-receiving device of a second experiment has the same configuration as the semiconductor light-receiving device of the first experiment except that the semiconductor light-receiving device of the second experiment does not include hole barrier layer HB and electron barrier layer EB and third III-V compound semiconductor layer 13 is a GaInAs layer of i-type.

### First Experiment Result

Energy band diagrams were created by simulation for the semiconductor light-receiving devices of the first experiment and the second experiment. A temperature T used in the simulation is 250 Kelvin (K). The bias voltage Vb applied to the semiconductor light-receiving device is −1 V. The results of the simulation are shown in FIGS. 4 and 5.

FIGS. 4 and 5 are graphs showing examples of energy band diagrams of semiconductor light-receiving devices of the first experiment and the second experiment, respectively. In the graphs of FIGS. 4 and 5, the horizontal axis represents the position (μm) in the thickness direction (first direction D1) of the optical absorption layer. The vertical axis represents energy (eV). In the graph, Ec represents the energy at the lower end of the conduction band, and Ev represents the energy at the upper end of the valence band.

As shown in FIG. 4, in the first experiment, a barrier for electrons is formed at the lower end of the conduction band by electron barrier layer EB, and a barrier for holes is formed at the upper end of the valence band by hole barrier layer HB. On the other hand, as shown in FIG. 5, in the second experiment, no barrier for electrons is formed at the lower end of the conduction band, and no barrier for holes is formed at the upper end of the valence band. Therefore, the hole barrier layer suppresses a flow of holes (minority carriers) in the n-type GaInAs layer into the optical absorption layer. The electron barrier layer suppresses the flow of electrons (minority carriers) in the p-type GaInAs layer into the optical absorption layer.

In FIG. 5, a notch is formed at the upper end of the valence band by the i-type GaInAs layer located between the optical absorption layer and the p-type GaInAs layer. The notch serves as a barrier when holes generated by light absorption in the optical absorption layer flow into the p-type GaInAs layer. On the other hand, in FIG. 4, the i-type GaInAsSb layer is located between the optical absorption layer and the p-type GaInAs layer. The height of the notch formed by the i-type GaInAsSb layer is smaller than the height of the notch in FIG. 5. Therefore, it is understood that the height of the notch can be reduced by adding antimony.

### Second Experiment Result

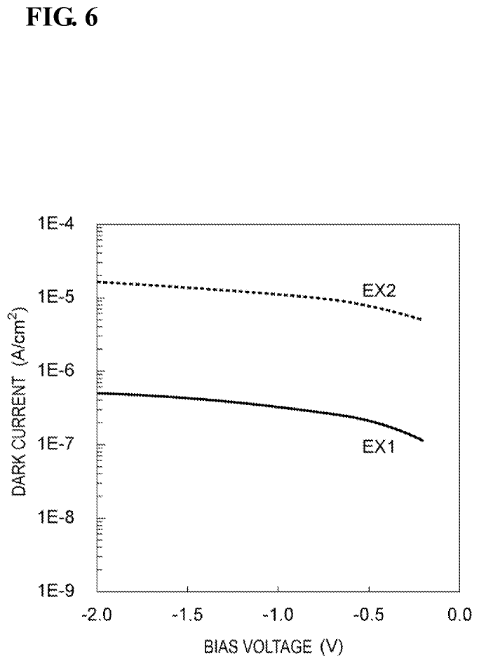

For the semiconductor light-receiving devices of the first experiment and the second experiment, the dark current with respect to the bias voltage was calculated by simulation. The temperature is 250 Kelvin (K). The results of the simulation are shown in FIG. 6.

FIG. 6 is a graph showing examples of the relationship between dark current and bias voltage of semiconductor light-receiving device in a first experiment and a second experiment. In the graph of FIG. 6, the horizontal axis represents the bias voltage (V) applied to the semiconductor light-receiving device. The vertical axis represents dark current (A/cm²). In the graph, EX1 indicates the result of the first experiment, and EX2 indicates the result of the second experiment.

As shown in FIG. 6, regardless of the bias voltage, the dark current of the semiconductor light-receiving device of the first experiment was 1/10 or less of the dark current of the semiconductor light-receiving device of the second experiment, which was very small.

Although the exemplary embodiments of the present invention have been described in detail, the present invention is not limited to the above-described embodiments.

The embodiments disclosed herein are to be considered in all respects as illustrative and not restrictive. The scope of the present invention is defined by the appended claims rather than the foregoing description, and is intended to include all modifications within the scope and meaning equivalent to the appended claims.

What is claimed is:

1. A semiconductor light-receiving device comprising:
an indium phosphide substrate;
a first III-V compound semiconductor layer of n-type;
a second III-V compound semiconductor layer of p-type;
an optical absorption layer disposed between the first III-V compound semiconductor layer and the second III-V compound semiconductor layer;
a hole barrier layer disposed between the first III-V compound semiconductor layer and the optical absorption layer; and
an electron barrier layer disposed between the second III-V compound semiconductor layer and the optical absorption layer,
wherein the first III-V compound semiconductor layer is disposed between the indium phosphide substrate and the optical absorption layer.

2. The semiconductor light-receiving device according to claim 1, wherein the optical absorption layer has a type-II superlattice structure.

3. The semiconductor light-receiving device according to claim 2, wherein the superlattice structure includes a gallium indium arsenide layer and a gallium arsenide antimonide layer.

4. The semiconductor light-receiving device according to claim 1, wherein the hole barrier layer is an n-type aluminum gallium indium arsenide layer.

5. The semiconductor light-receiving device according to claim 1, wherein the hole barrier layer is a bulk layer.

6. The semiconductor light-receiving device according to claim 1, wherein the electron barrier layer is a p-type aluminum gallium arsenide antimonide layer.

7. The semiconductor light-receiving device according to claim 1, wherein the electron barrier layer is a bulk layer.

8. The semiconductor light-receiving device according to claim 1, further comprising a non-doped third III-V compound semiconductor layer disposed between the electron barrier layer and the optical absorption layer.

9. The semiconductor light-receiving device according to claim 8, wherein the third III-V compound semiconductor layer contains gallium indium arsenide antimonide.

10. The semiconductor light-receiving device according to claim 1, further comprising a non-doped fourth III-V compound semiconductor layer disposed between the hole barrier layer and the optical absorption layer.

11. The semiconductor light-receiving device according to claim 10, wherein the fourth III-V compound semiconductor layer contains gallium indium arsenide.
